(19) United States
(12) Patent Application Publication
(10) Pub. No.: US 2008/0268352 A1
(43) Pub. Date: Oct. 30, 2008

(54) LIGHT REFLECTION MASK, METHOD OF MANUFACTURING THE SAME AND SEMICONDUCTOR DEVICE

(76) Inventor: Kosuke TAKAI, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/109,552

(22) Filed: Apr. 25, 2008

(30) Foreign Application Priority Data
Apr. 27, 2007 (JP) 2007-119331

(51) Int. Cl. G03F 1/00; G03F 7/20

(52) U.S. Cl. 430/5; 430/319

(57) ABSTRACT

Provided is a method of producing a light reflection mask in which flatness of a front surface thereof is less deteriorated by light reflection pattern formation and during electrostatic chucking. Thereby, the light reflection mask contributes to improvement of exposure accuracy in EUV exposure or the like. The method includes the steps of: measuring flatness of the front surface of a substrate that has the front surface on which a reflection mask pattern is formed, and a back surface on which a conductive film for the electrostatic chucking is formed; and selectively removing, on the basis of the measured flatness, the conductive film to form an opening therein, thereby causing the conductive film in the mask to have an open-area-ratio variation that allows the front surface of the substrate to have a desired flatness.

### CROSS-REFERENCE TO RELATED APPLICATIONS

This application is based upon and claims the benefit of priority from prior Japanese Patent Application No. 2007-119331, filed Apr. 27, 2007, the entire contents of which are incorporated herein by reference.

### BACKGROUND OF THE INVENTION

1. Field of the Invention

The present invention relates to: a light reflection mask for lithography that uses an extreme ultra-violet (EUV) light, or the like; and a method of producing the light reflection mask. Moreover, the present invention relates to a method of manufacturing a semiconductor device by using the light reflection mask.

2. Description of the Related Art

Lithography using an EUV light with a wavelength of approximately 13.5 nm utilizes a light reflection mask having a light reflection pattern formed on a substrate therein. The light reflection mask is required to have an extremely high degree of flatness. For example, the allowable level difference in the light reflection mask used in EUV exposure is said to be on the order of several tens of nm.

Generally, the light reflection mask is formed of a mask blank. In the mask blank, a light reflecting layer and a light absorbing layer are stacked on the front surface of a glass substrate, and a conductive film is formed on the back surface of the substrate. Incidentally, even if a mask blank has a fine flatness that satisfies a reference value, this flatness is likely to be deteriorated after the front surface of the substrate is processed (the light absorbing layer is patterned). This is because such processing is likely to cause stress imbalance in the mask substrate between a region with low pattern density and a region with a high pattern density. Since a EUV beam is obliquely incident on the light reflection mask during EUV exposure, the deterioration in the flatness of the light reflection mask naturally leads to a serious problem that the pattern obtained as a result of the EUV exposure is displaced.

Moreover, in the EUV exposure, a light reflection mask is used while the back surface thereof is electrostatically chucked so that the light-reflection-pattern surface can face down. Accordingly, during the EUV exposure, the light-reflection-pattern surface suffers from not only the flatness deterioration by the aforementioned density difference in the pattern, but also the deformation caused by the weight of the mask substrate itself. Thus, the flatness management of the mask during the EUV exposure is critical.

Meanwhile, a method for improving flatness of a light reflection mask has been proposed. In such a method, flatness of the front surface of a glass substrate is measured, and in accordance with the measured flatness, the front surface of the substrate is polished (refer to, for example, Japanese Patent Application Publication No. 2004-310067). However, it is true that this method can make the substrate itself flat by processing, but it cannot prevent the flatness deterioration of the mask substrate caused by pattern formation and caused while the light reflection mask is set in an exposure apparatus.

As described above, the front surface flatness of a light reflection mask used for EUV exposure or the like has been deteriorated by reflection pattern formation and during electrostatic chucking, and this flatness deterioration has been reduced the exposure accuracy.

### SUMMARY OF THE INVENTION

In accordance with an aspect of the invention, there is provided a method of manufacturing a light reflection mask, comprising: obtaining a flatness of one surfaces of a substrate when a mask pattern is formed on the surface of the substrate and a conductive film is formed on the another surface of the substrate; and removing the conductive film selectively to form at least one opening in the conductive film based on the flatness.

In accordance with an aspect of the invention, there is provided a light reflection mask, comprising: a mask pattern formed on one surface of the substrate; and a conductive film having at least one opening formed on another surface of the substrate.

In accordance with an aspect of the invention, there is provided a method of manufacturing semiconductor device, comprising: chucking a light reflection mask onto a mask stage of an exposure apparatus, the mask comprising a mask pattern on one surface of a substrate and a conductive film having at least one opening formed on another surface of the substrate; transferring the mask pattern of the mask onto a semiconductor substrate using the exposure apparatus.

### BRIEF DESCRIPTION OF THE DRAWINGS

FIG. 1 is a flowchart showing a producing procedure of a light reflection mask according to a first embodiment of the present invention.

FIGS. 2A to 2C are cross-sectional views showing manufacturing steps of the light reflection mask.

FIG. 3A is a cross-sectional view showing a light reflection mask in which substrate flatness thereof is deteriorated due to an open-area-ratio variation in its pattern surface; FIG. 3B is a cross-sectional view showing the light reflection mask in which a conductive film on its back surface is processed, so that the substrate flatness is improved.

FIG. 4 is a cross-sectional view showing the light reflection mask electrostatically chucked onto a mask stage of an exposure apparatus.

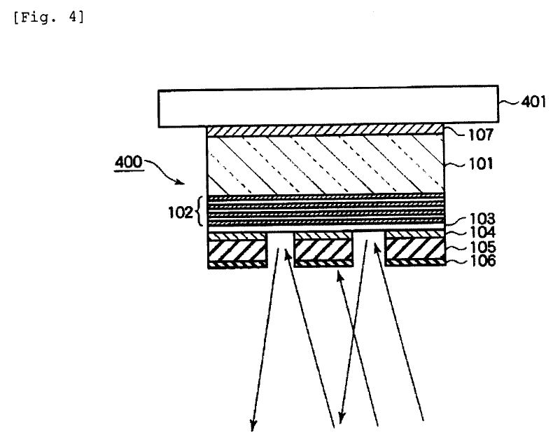

FIG. 5 is a schematic diagram illustrating transferred-pattern displacement caused when the flatness of the light reflection mask is deteriorated.

FIG. 6 is a flowchart showing a determination process of a pattern into which the back surface of the light reflection mask is to be processed, according to the first embodiment.

FIG. 7 is a cross-sectional view showing a schematic configuration of a light reflection mask according to a second embodiment.

### DESCRIPTION OF THE PREFERRED EMBODIMENTS

Hereinafter, description will be given of the present invention in detail according to embodiments shown in the drawings.

### First Embodiment

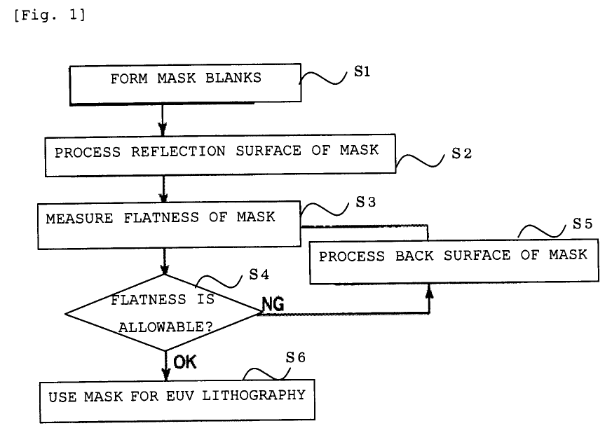

FIG. 1 is a flowchart showing a producing procedure of a light reflection mask according to a first embodiment of the present invention.

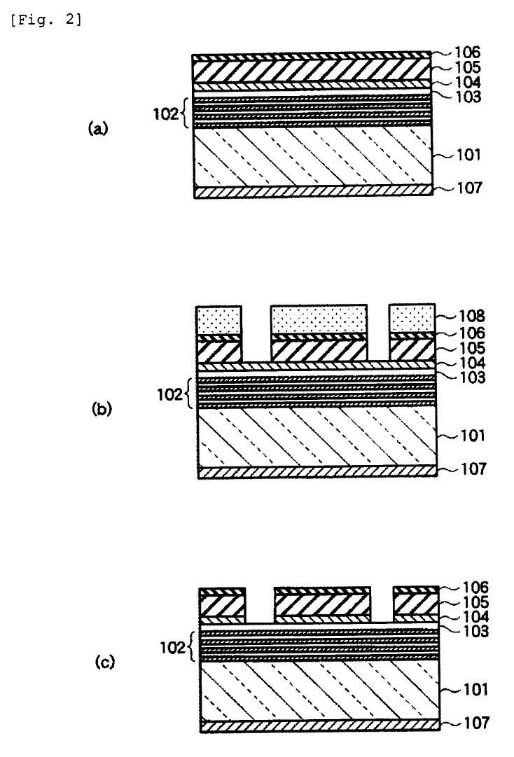

Firstly, a mask blank used for EUV exposure is formed (Step S1). Specifically, as shown in FIG. 2A, approximately 40 layers of molybdenum (Mo) layers and silicon (Si) layers are alternatively stacked, by sputtering, on the front surface of a glass substrate 101 having an extremely small thermal expansion coefficient, and thereby a multilayer reflecting film 102 is formed on the substrate 101. In this process, the multilayer reflecting film 102 is formed such that the uppermost layer thereof can be a Si layer (cap layer) 103 to protect the front surface of the multilayer reflecting film 102.

Subsequently, a chromium (Cr) film to serve as a buffer layer 104 is formed on the Si cap layer 103. Thereafter, a tantalum nitride (TaN) layer to serve as an absorbing layer 105 of EUV light, and a tantalum oxide (TaO) layer to serve as an absorbing layer (anti-reflection film) 106 of inspection light with a wavelength of approximately 250 nm are sequentially formed on the buffer layer 104. In addition, on the back surface of the substrate 101, a Cr film is formed as a conductive film 107 which is to be electrostatically chucked during EUV exposure. Here, the conductive film 107 is not limited to a Cr film, but has only to be conductive so as to be electrostatically chucked. Note that, however, the conductive film 107 should preferably be made of the same material as that of the buffer layer 104 which is the lowermost layer to be processed on the front surface side of the substrate 101.

In general, as a flatness specification of a mask blank used for EUV exposure, allowable flatness difference in a mask blank is set to approximately 50 nm. However, there are stresses even in a mask blank that satisfies this flatness specification. In a temperature range around an ordinary temperature (20° C.), the coefficients of linear thermal expansion of Cr, Si and Mo are 4.9 (1/K), 2.6 (1/K) and 4 (1/K), respectively. Moreover, under the same condition, the coefficient of linear thermal expansion of a glass substrate is as extremely small as 0.05 (1/K). Accordingly, during EUV exposure, there are stresses in all the interfaces between the different layers including the “Cr buffer layer and Si cap layer” interface and the “glass substrate and back Cr film” interface, in the mask blank. These stresses are caused by a difference in a substrate temperature between during the film formation processes and during the EUV exposure process.

Next, the mask blank is formed into the light reflection mask with a desired pattern (Step S2). Specifically, as shown in FIG. 2B, a resist is applied on the front surface of the mask blank formed according to the aforementioned procedure, and thereafter the desired pattern is written by using an electron beam. Subsequently, a post exposure bake (PEB) process and a development process are performed on the resist, so that a resist pattern 108 is formed. Then, the absorbing layers 105 and 106 are selectively etched by a plasma process using the resist pattern 108 as a mask. Then, after a defect inspection process and a correction process are performed, the buffer layer 104 is selectively etched through a plasma process again, as shown in FIG. 2C.

Now, the shape-forming processing on the mask is complete, and the thus-formed mask substrate naturally includes regions in which the buffer layer 104 on the Si cap layer 103 is removed off by etching, and regions in which the buffer layer 104 remains. In the regions in which the buffer layer 104 is removed off, the Si cap layer 103 is free from the stress in the direction of the above-described interface between the Si cap layer 103 and the buffer layer 104, while this interface stress remains in the regions in which the buffer layer 104 remains. In other words, there is a stress variation in the mask substrate. This variation causes flatness deterioration in the mask substrate.

Thus, when the processing on the front surface of the mask is complete, the front surface flatness of the mask substrate is measured with a flatness measuring apparatus utilizing optical interference, or the like (Step S3). In this measurement, of particular note is the height difference between a region having a relatively high open area ratio in its pattern surface and a region having a relatively low open area ratio in its pattern surface. This is because, even if the mask blank to be formed into the mask substrate satisfy their flatness specification, this flatness is likely to be deteriorated by the imbalance in the aforementioned interface stresses in the mask substrate attributable to density difference (open-area-ratio variation) in the written pattern.

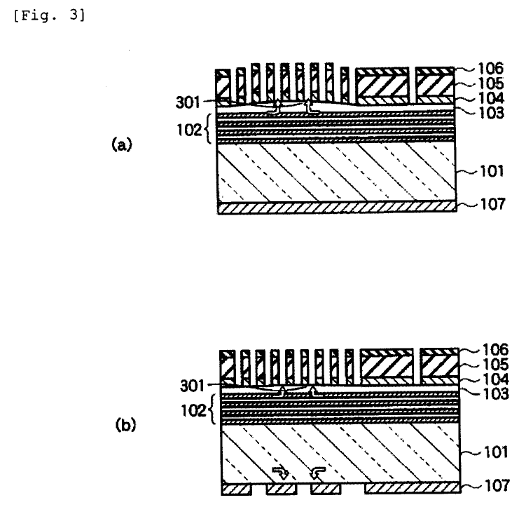

Here, suppose the case where the flatness measurement result shows that the region having a high open area ratio is convex as shown in shown in FIG. 3A, as an example. The displacement amount of the pattern that would be obtained as a result of EUV lithography using this mask can be calculated herein. Thus, it is determined whether or not the thus-calculated displacement amount falls within the manufacturing specifications of a device (Step S4). If the displacement amount does not fall within the manufacturing specifications, the back Cr film (conductive film 107) is processed as shown in FIG. 3B so that the flatness of the mask can be adjusted (Step S5). Specifically, the back Cr film is processed as follows. Firstly, a resist is applied on the back surface of the mask, and thereafter a pattern is written on the back surface by using an electron beam or a laser beam. Then, after a PEB process and a development process are performed, the back Cr film is etched by plasma etching.

Here, what pattern the back Cr film should be processed into is determined in consideration of the following effects.
Flatness change caused by a stress balance in the interface between the back Cr film and the glass substrate
Deformation of the substrate caused by the weight thereof while the substrate is electrostatically chucked
Flatness change caused by nonuniformity in electrostatic force attributable to unevenness of the conductive film in the back surface of the mask substrate, while the substrate is electrostatically chucked

In consideration of these effects, what shape the back Cr film should be processed into is determined on the basis of the measured flatness so that the flatness degree of the mask substrate can be optimal when the mask substrate is electrostatically chucked after the back Cr film is processed.

For example, in the case where the region having a relatively high open area ratio is convex as described above, the back Cr film in a region vertically beneath the convex region is processed as shown in FIG. 3B so that the stress balance in the interface between the back Cr film and the glass substrate can be adjusted. Thereby, fine flatness can be provided while the mask substrate is electrostatically chucked.

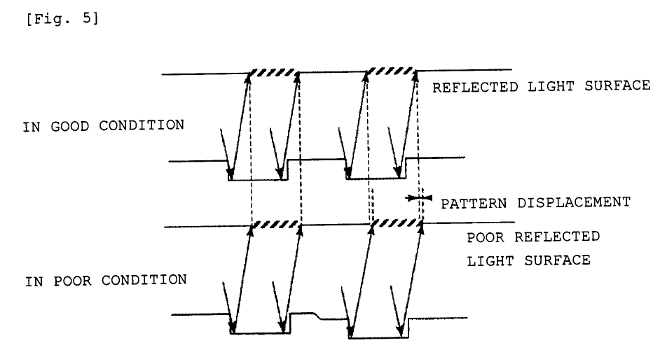

Here, in the case where EUV exposure is performed by using a light reflection mask, the light reflection mask 400 is used in a manner that the back surface thereof is electrostatically chucked onto the bottom surface of a mask stage 401 so that the reflecting-film surface of the light reflection mask 400 can face down. Accordingly, during the EUV exposure, the reflecting-film surface suffers from not only the flatness deterioration by the aforementioned density difference in the pattern, but also the deformation caused by the weight of the mask substrate itself. Thus, the flatness management of the mask substrate during the EUV exposure is critical. Since the EUV beam is obliquely incident on the light reflection mask during the EUV exposure, the deterioration in the flatness of the light reflection mask naturally causes an serious problem that a pattern obtained as a result of the EUV exposure is displaced as shown in FIG. 5. Therefore, as in this embodiment, it is important to measure the flatness of the light reflection mask under a condition in which the light reflection mask is electrostatically chucked onto the stage of an exposure apparatus instead of measuring the flatness of the light reflection mask while being in a free state.

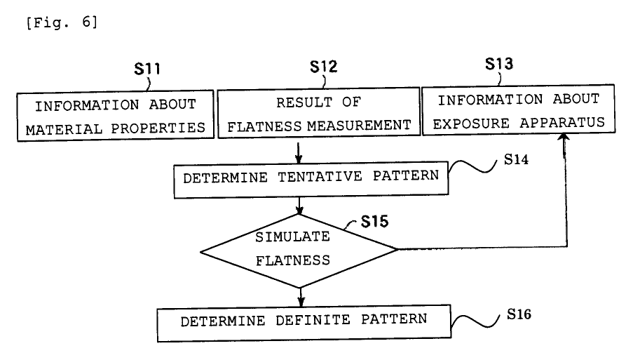

FIG. 6 shows a flowchart of the determination process of the pattern into which the back surface of the light reflection mask is to be processed. Firstly, a tentative pattern is designed (S14). In this designing, the measured flatness (S12) and material properties (S11), such as a kind, a film thickness and a thermal expansion coefficient of each material constituting the mask, are given as constant values; and a voltage value of the exposure apparatus during the electrostatic chucking (including dividedly electrostatic chucking) is used as information on the exposure apparatus (S13), and is given as a parameter for the designing. Then, the substrate flatness of the light reflection mask having the back surface processed into the thus-designed tentative pattern is simulated (S15). If the flatness shown by this simulation is poor, the designing using a different parameter of information on the exposure apparatus is repeatedly preformed. If the flatness shown by this simulation is acceptable, the corresponding tentative pattern is determined as the definite pattern (S16).

When the pattern of the thus-formed light reflection mask was transferred on a sample, such as a semiconductor wafer, by EUV exposure, a favorable pattern was printed on the sample since the mask substrate has the flat front surface, so that no pattern displacement occurred during the EUV exposure.

As described above, the light reflection mask production method according to this embodiment includes the following steps. Specifically, the flatness of the front surface, on which the reflection mask pattern is formed, of the substrate 101 is measured while the substrate 101 is electrostatically chucked onto the mask stage of the exposure apparatus. Then, on the basis of the measured flatness, the conductive film 107 is selectively removed so as to have openings, and thereby the conductive film 107 in the mask is caused to have an open-area-ratio variation that allows the front surface of the substrate 101 to have a desired flatness. This can suppress the deterioration of the flatness of the front surface of the mask substrate caused by reflection pattern formation and during the electrostatic chucking, and thereby can contribute to improvement of exposure accuracy in EUV exposure or the like. In other words, in the light reflection mask production process according to this embodiment, the flatness of the mask substrate is measured after the pattern formation surface is patterned, and according to the thus-measured flatness, the back conductive film of the mask substrate is processed so that the mask substrate can have appropriate flatness. This makes it possible to adjust the flatness deterioration value within an appropriate range for the exposure.

### Second Embodiment

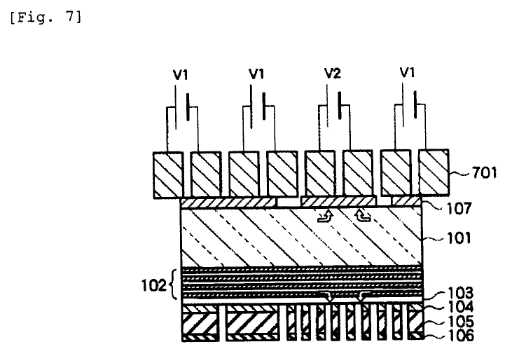

FIG. 7 is a cross-sectional view showing a schematic configuration of a light reflection mask according to a second embodiment of the present invention. Note that the same components as in FIG. 2 are denoted by the same reference signal, and the detailed description thereof will be omitted. The reference numeral 701 in FIG. 7 represents electrodes of a divided electrostatic chuck.

This embodiment is a combination of the light reflection mask described in the first embodiment and a divided electrostatic chuck (refer to Japanese Patent Application Publication No. 2006-135062).

The back Cr film (conductive film 107) is processed as in the first embodiment, and however, in this embodiment, the back Cr film is caused to have isolated islands in which the back Cr film is electrically isolated from the surrounding regions. When this type of light reflection mask is electrostatically chucked with the divided electrostatic chuck, it is possible to cause the back Cr film of the light reflection mask to have different adhesive forces from one isolated island to another, since the back Cr film is divided into the islands. Thus, if the electrostatic chuck voltages are controlled so that the islands, located vertically beneath the front convex region, of the back Cr film can have a stronger electrostatic force than the other islands, the overall flatness can be improved, as well. Specifically, in FIG. 7, if the electrostatic chuck voltages are controlled such that V2>V1 can be satisfied, the back Cr film in a region having a high open area ratio has a stronger adhesive force than in the other regions, so that the convexity of the front surface can be reduced.

Note that, in the case where the divided electrostatic chuck is employed, the flatness of the mask substrate can be improved to some extent even though the back Cr film is not processed. However, the processing of the back Cr film makes it possible to apply a different force to a desired region in the mask substrate, and thus enables a more effective flatness control.

As described above, according to this embodiment, the back Cr film is processed on the basis of the measured flatness of the mask substrate, so that the flatness deterioration of the mask substrate can be corrected. Thus, this embodiment can provide a similar effect as the aforementioned first embodiment. In addition, a divided electrostatic chuck is employed in this embodiment, so that the flatness of the substrate can further be improved. For example, if the flatness deterioration amount of the substrate caused by the reflection pattern formation is more than correctable by the processing of the back Cr film alone, the flatness deterioration remaining uncorrected after the processing of the back Cr film can be corrected by the divided electrostatic chuck which is capable of generating different adhesive forces from one spot to another.

### Modification

Note that the present invention is not limited to the aforementioned embodiments. In the aforementioned embodiments, the flatness of the front surface of the mask substrate is measured while the mask substrate is electrostatically chucked onto the mask stage of the exposure apparatus. However, in the case where the flatness deterioration of the mask substrate caused during the electrostatic chucking presents no problem, the front-surface flatness of the mask substrate is not necessarily measured with the mask substrate being electrostatically chucked, but may be measured in a free state.

Moreover, in the aforementioned embodiments, the back conductive film is processed by means of the plasma process, but the back conductive film may be processed by other methods. For example, the conductive film may be partially removed with a focused ion beam, or may be physically scrapped off using a probe of a scanning probe microscope (SPM). Which one of these methods to employ may be determined on a case-by-case basis, in view of throughput of the light reflection mask production processes. For example, if a large area of the back surface is processed into a pattern, plasma etching may be employed, and if not, a focused ion beam method may be employed.

Furthermore, the light reflection mask is not limited to a configuration obtained by sequentially stacking a reflecting layer and an absorbing layer on the front surface of a mask substrate, and by thereafter patterning the absorbing layer. Alternatively, the light reflection mask may have a configuration obtained by sequentially stacking an absorbing layer and a reflecting layer on the front surface of a mask substrate, and by thereafter patterning the reflecting layer. Moreover, materials, thicknesses and the like of the reflecting layer, the absorbing layer and the back conductive film can be modified appropriately, in accordance with the specifications.

In addition to the aforementioned modifications, the present invention can be implemented in various modified forms without departing from the gist thereof.

What is claimed is:

1. Method of manufacturing a light reflection mask, comprising:
obtaining a flatness of one surfaces of a substrate when a mask pattern is formed on the surface of the substrate and a conductive film is formed on the another surface of the substrate; and
removing the conductive film selectively to form at least one opening in the conductive film based on the flatness.

2. The method according to claim 1, wherein the flatness of the substrate is obtained while the substrate is electrostatically chucked onto a mask stage of an exposure apparatus.

3. The method according to claim 1, wherein the openings are formed to keep a displacement amount between a transferred pattern of the mask pattern and a design pattern of the transferred pattern by an exposure apparatus within a manufacturing specification.

4. The method according to claim 1, wherein the mask pattern includes a first mask pattern region and a second mask pattern region, a degree of a pattern density of the first mask pattern region being lower than that of the second mask pattern region and an open-area-ratio of a conductive film region at the opposite side of the first mask pattern region being lower than that of a conductive film region at the opposite side of the second mask pattern region.

5. The method according to claim 2, wherein a design of the opening is determined based on information about material of the substrate, the flatness of the substrate, and the exposure apparatus.

6. The method according to claim 1, wherein the flatness of the substrate is obtained by performing simulation using information about a design of the opening, material of the substrate, the flatness of the substrate, and the exposure apparatus.

7. The method according to claim 1, wherein the flatness of the substrate is obtained while the substrate is not chucked on a stage of an exposure apparatus.

8. The method according to claim 1, wherein the opening is formed by plasma etching.

9. The method according to claim 1, wherein the opening is formed by a focused ion beam method.

10. The method according to claim 1, wherein the substrate has a stacked layer having a cap layer and a buffer layer on the cap layer and the mask pattern is formed to remove the buffer layer and to partly expose the cap layer.

11. The method according to claim 10, wherein the conductive film and the buffer layer include the same material.

12. The method according to claim 11, wherein the cap layer is Si layer and the buffer layer is Cr layer.

13. A light reflection mask, comprising:
a mask pattern formed on one surface of the substrate; and
a conductive film having at least one opening formed on another surface of the substrate.

14. The mask according to claim 13, wherein the mask pattern includes a first mask pattern region and a second mask pattern region, a degree of a pattern density of the first mask pattern region being lower than that of the second mask pattern region and an open-area-ratio of a conductive film region at the opposite side of the first mask pattern region being lower than that of a conductive film region at the opposite side of the second mask pattern region.

15. A method of manufacturing semiconductor device, comprising:
chucking a light reflection mask onto a mask stage of an exposure apparatus, the mask comprising a mask pattern on one surface of a substrate and a conductive film having at least one opening formed on another surface of the substrate;
transferring the mask pattern of the mask onto a semiconductor substrate using the exposure apparatus.

16. The method according to claim 15, wherein the opening is formed based on a flatness of the mask substrate when the mask substrate is chucked onto the mask stage of the exposure apparatus.

17. The method according to claim 15, wherein voltage applied to the conductive film is controlled during exposure.

18. The method according to claim 17, wherein the voltage applied to the conductive film during exposure is controlled based on flatness of the mask substrate.

19. The method according to claim 17, wherein the mask pattern includes a first mask pattern region and a second mask pattern region, a degree of a pattern density of the first mask pattern region being lower than that of the second mask pattern region and a voltage applied to a conductive film region at the opposite side of the first mask pattern region being lower than that of a conductive film region at the opposite side of the second mask pattern region.

20. The method according to claim 19, wherein the conductive film region at the opposite side of the first mask pattern region and the conductive film region at the opposite side of the second mask pattern region are isolated and each of the regions is separately chucked by a divided electrostatic chuck.
